(19) United States
(12) Patent Application Publication
(10) Pub. No.: US 2017/0021377 A1
(43) Pub. Date: Jan. 26, 2017

(54) Transfer Printing Plate and Method for Manufacturing the same

(71) Applicants: BOE Technology Group Co., Ltd., Beijing (CN); Hefei BOE Optoelectronics Technology Co., Ltd., Anhui (CN)

(72) Inventor: Yan Wang, Beijing (CN)

(21) Appl. No.: 15/097,427

(22) Filed: Apr. 13, 2016

(30) Foreign Application Priority Data
Jul. 20, 2015 (CN) 201510428246.3

(51) Int. Cl. B05C 1/02; G03F 7/16; G02F 1/1337; G03F 7/20

(52) U.S. Cl. CPC B05C 1/025; G03F 7/20; G03F 7/16; G02F 1/133788

(57) ABSTRACT

Disclosed is a transfer printing plate and a method for manufacturing the same to solve the problem in the prior art that a thickness of an alignment film is not uniform due to a clog of via holes in a display substrate with protrusions on the transfer printing plate when forming the alignment film by the transfer printing plate. The transfer printing plate comprises a substrate and a plurality of protrusions disposed on and protruding from the substrate and spaced apart from each other, wherein a top end of at least one protrusion is provided with a recess for receiving an alignment liquid, when via holes in the substrate to be aligned are covered with the protrusions, the alignment liquid in the recess forms the alignment film in the via holes.

### CROSS-REFERENCE TO RELATED APPLICATION

This application claims the benefit of Chinese Patent Application No. CN201510428246.3 filed on Jul. 20, 2015 in the State Intellectual Property Office of China, the whole disclosure of which is incorporated herein by reference.

### BACKGROUND OF THE INVENTION

Field of the Invention

Embodiments of the disclosure relate to field of liquid crystal technique, in particularly to a transfer printing plate for forming an alignment film and a method for manufacturing the same.

Description of the Related Art

A Thin Film Transistor Liquid Crystal Display (TFT-LCD) is recently developed widely and has become a main stream of a display in the market, and thus become a desired display device for a consumer and the market due to its small volume, low power consumption, radiationless property and the like.

A crystal display panel mainly comprises an array substrate, a color film substrate and a liquid crystal cell formed by liquid crystal layers sandwiched between the array substrate and the color film substrate. In the crystal display panel, in order to bring a liquid crystal molecule into a certain orientation, it is necessary to form alignment films on display regions of the array substrate and the color film substrate of the crystal liquid panel, respectively. The alignment films on either side are configured to control a passage of a light. The array substrate and the color film substrate are collectively called as the display panel.

In the prior art, the alignment film is generally formed by transferring an alignment liquid onto a surface of the display panel by a transfer printing plate and then curing. The surface of the transfer printing plate in the prior art is provided with a plurality of protrusion protruding therefrom. As shown in FIG. 1, the transfer printing plate comprises a substrate 101, a plurality of protrusions 102 disposed on and protruding from the substrate 101 and having a frustum cone shape, the protrusions 102 being spaced apart from each other. Referring to FIG. 2, during forming the alignment film, the alignment liquid is firstly filled into spaces 103 between the protrusions 102 of the transfer printing plate and then transferred onto a display substrate 2 by means of printing.

As the liquid crystal display panel is gradually expanded and updated for display application in a mobile terminal, a higher requirement is requested for a resolution of the liquid crystal panel by the market and consumer and the resolution of the display panel for all purpose continuously increases. As the resolution increases, diameters of various via holes 21 disposed in the substrate are getting smaller. However, in order to prevent the protrusions 102 from being fractured, a diameter of a top end of each protrusion 102 on the transfer printing plate can not be made smaller than that of each via hole 21 due to a restriction to a technological level. Therefore, during forming the alignment film by the transfer printing plate, the via holes 21 are often clogged with the protrusions 102, which results in a poor printing of the alignment liquid in the via hole region and an uneven thickness of the alignment film, thereby eventually causing a poor display of the liquid crystal display panel.

### SUMMARY OF THE INVENTION

Embodiments of the disclosure provide a transfer printing plate and a method for manufacturing the same to solve the problem in the prior art that a thickness of an alignment film is not uniform due to a clog of via holes in a display substrate with protrusions on the transfer printing plate when forming the alignment film by the transfer printing plate.

According to an aspect of the disclosure, there is provided a transfer printing plate for forming an alignment film comprising a substrate; and a grid point structure comprising a plurality of protrusions disposed on the substrate and spaced apart from each other, wherein at least one of the plurality of protrusions is provided with a recess at a top end thereof for receiving an alignment liquid, and wherein the alignment liquid in the recess forms the alignment film in the via hole when a via hole in a display substrate to be aligned is blocked by the protrusion.

With the transfer printing plate of the embodiments of the present application, the transfer printing plate comprises a substrate and a plurality of protrusions disposed on and protruding from the substrate, wherein the top end of the at least one protrusion is provided with a recess for receiving a certain amount of the alignment liquid, and an alignment film is formed in the via hole by printing the alignment liquid in the recess when the via hole in the display substrate to be aligned is blocked by the protrusion during forming the alignment film, such that a relatively complete alignment film is formed. Therefore, the problem that a via hole region can not be formed with the alignment film due to blocking of the via hole. As a result, a uniform alignment film is obtained and a display quality of a display panel can be improved.

Typically, the recess has a rectangular, trapezoidal or triangular shape in cross-section.

It is easy to form the recess in the protrusion by a patterning process when the recess has a rectangular, trapezoidal or triangular shape in cross-section.

Typically, when the recess has the trapezoidal shape in cross-section, an upper side of the trapezoidal shape has a size of 5 to 15 μm, and a lower side thereof has a size of 2 to 5 μm.

In a case where the upper side is 5 to 15 μm and the lower side is 2 to 5 μm, the recess has a reversed trapezoidal shape, which can be easily formed by a photo-lithographic process in the art. Further, in the prior art, a diameter of the top end of each protrusion is typically 10 to 40 μm. When the upper side of the trapezoidal recess is set as 5 to 15 μm and the lower side thereof is set as 2 to 5 μm, a side wall of the top end of each protrusion will not be too thin to be fragile, and the alignment liquid can be ensured to flow into the recess smoothly.

Typically, a depth of the recess in a direction perpendicular to the substrate is 5 to 10 μm.

It is possible to ensure the recess to be filled with a certain amount of the alignment liquid so that a complete alignment film can be formed in via hole regions where the via holes are blocked by the protrusions when the upper side of the trapezoidal recess is 5 to 15 μm and the lower side thereof is 2 to 5 μm and the depth thereof in the direction perpendicular to the substrate is 5 to 10 μm.

Typically, the protrusion is made of resin material.

Based on the same inventive concept, according to an embodiment of the invention, there is provided with a method for manufacturing a transfer printing plate, comprising: providing a substrate; forming a plurality of protrusions protruding and spaced apart from each other on the substrate; and forming a recess at a top end of at least one protrusion, the recess is configured to receive an alignment liquid, and the alignment liquid in the recess forms the alignment film in a via hole when the via hole in a display substrate to be aligned is blocked by the protrusion.

In the protrusions formed by the method according to the embodiment of the invention, the top end of the at least one protrusion is provided with the recess for receiving a certain amount of the alignment liquid, and the alignment liquid in the recess forms the alignment film by printing the alignment liquid in a via hole when the via hole in the display substrate to be aligned is blocked by the protrusion during forming the alignment film, such that a relatively complete alignment film can be formed. Therefore, the problem that a via hole region can not form the alignment film due to blocking of the via hole can be avoided, thus a uniform alignment film can be obtained and a display quality of a display panel can be improved.

According to an exemplary embodiment of the disclosure, the method for forming the transfer printing plate particularly comprises:

coating resin material on the substrate to form a resin layer;

applying photoresist on the resin layer;

forming the protrusions including the recesses through a patterning process by a mask plate including a complete shielding region, a light transmitting region and a half-shielding region, wherein the half-shielding region corresponds to the recess, and the complete shielding region or the light transmitting region corresponds to a remaining part of the protrusion expect the recess.

### BRIEF DESCRIPTION OF THE DRAWINGS

The above and other features of the present invention will become more apparent by describing in detail exemplary embodiments thereof with reference to the accompanying drawings, in which:

FIG. 1 is a schematic cross-section structural view of a transfer printing plate in the prior art;

FIG. 2 is a schematic view of a method for forming an alignment film by the transfer printing plate in the prior art;

FIG. 3 is a schematic cross-section structural view of a transfer printing plate according to an exemplary embodiment of the disclosure;

FIG. 4 is a schematic view of a method for forming an alignment film by the transfer printing plate according to an exemplary embodiment of the disclosure;

FIG. 5 is a schematic cross-section structural view of the transfer printing plate having protrusions with a recess having a triangular shape in cross-section according to an exemplary embodiment of the disclosure; and

FIG. 6 is a schematic cross-section structural view of the transfer printing plate having protrusions with a recess having a rectangular shape in cross-section according to an exemplary embodiment of the disclosure.

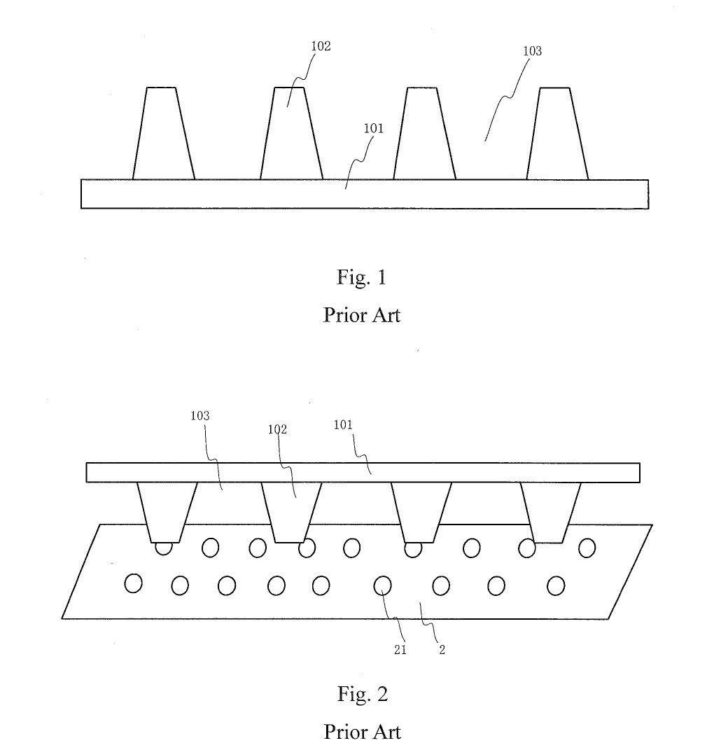

### DETAILED DESCRIPTION OF PREFERRED EMBODIMENTS OF THE INVENTION

Embodiments of the disclosure provide a transfer printing plate and a method for manufacturing the same to solve the problem in the prior art that a thickness of an alignment film is not uniform due to blocking of via holes in a display substrate by protrusions on the transfer printing plate when forming the alignment film by the transfer printing plate.

Embodiments of the disclosure will be clearly and completely described hereinafter with reference to the accompanying drawings. Obviously, the described embodiments are merely part of the embodiments of the disclosure, rather than all of the embodiments of the disclosure. Based on the embodiments of the disclosure, other embodiments acquired by the person skilled in the art without any inventive steps will be within the scope of the disclosure. In the description of the embodiments, the same or similar components are denoted by the same reference numerals.

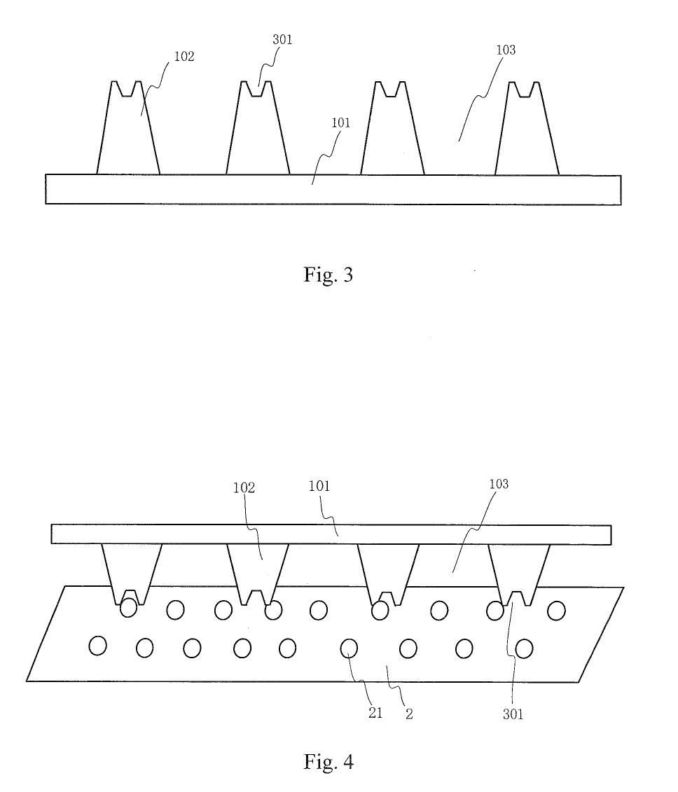

As shown in FIG. 3, a transfer printing plate for forming an alignment film is shown. The transfer printing plate comprises a substrate 101 and a plurality of protrusions 102 disposed on and protruding from the substrate 101 and spaced apart from each other. The plurality of protrusions 102 forms a grid point structure. Further, a top end of each protrusion 102 is provided with a recess 301, the spaces 103 between the protrusions 102 and the recesses 301 are used for receiving alignment liquid.

Typically, each of the recess 301 is centrally disposed at the top end of the respective protrusion 102.

According to other embodiments, it is possible that only the top ends of some of the protrusions 102 are provided with the recesses 301.

When forming the alignment film by the transfer printing plate, as shown in FIG. 4, the spaces 103 between the protrusions 102 and the recesses 301 both are filled with alignment liquid. When via holes 21 in a display substrate to be aligned are covered by the protrusions 102, the alignment liquid in the recesses 301 forms the alignment film in the via holes 21.

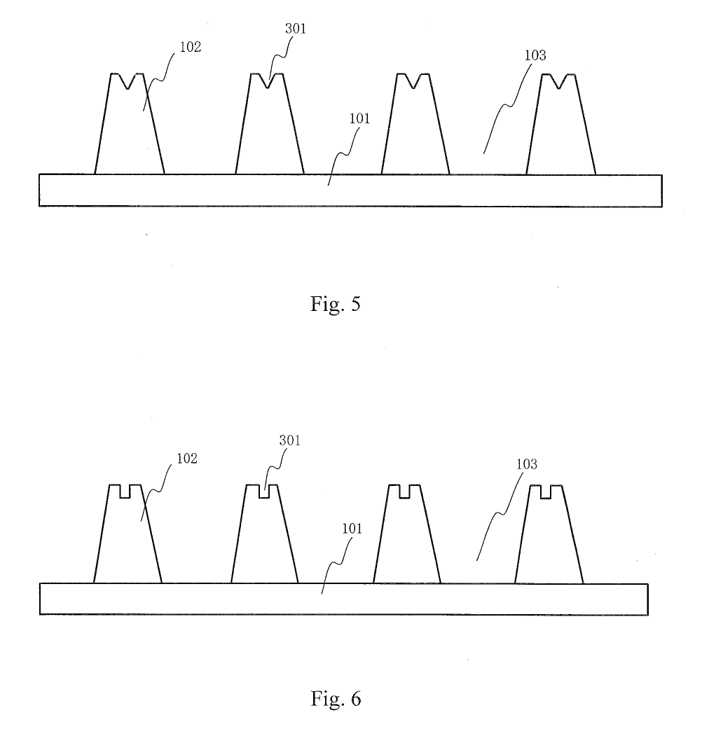

specifically, each of the recesses 301 has a trapezoidal shape in cross-section. In particular, during manufacturing the transfer printing plate, it is possible to form the recess 301 having a rectangular or triangular shape in cross-section, as illustrated in FIGS. 5 and 6. FIG. 5 is a schematic cross-section structural view of the transfer printing plate having protrusions with recesses having a triangular shape in cross-section according to an exemplary embodiment of the disclosure, and FIG. 6 is a schematic cross-section structural view of the transfer printing plate having protrusions with recesses having a rectangular shape in cross-section according to an exemplary embodiment of the disclosure.

The recess can be easily formed through a patterning process when the recess has a rectangular, trapezoidal or triangular shape in cross-section.

alternatively, the recess may also have other shapes such as a semicircular or polygonal shape in cross-section.

Moreover, when the recess has the trapezoidal shape in cross-section, an upper side thereof has a size of 5 to 15 μm, and a lower side thereof has a size of 2 to 5 μm.

In a case where the upper side is 5 to 15 μm and the lower side is 2 to 5 μm, the recess has a reversed trapezoidal shape, which can be easily formed by an existing photoetching process. Further, in the prior art, a diameter of the top end of each protrusion is typically 10 to 40 μm . Thus, when the upper side of the trapezoidal recess is set as 5 to 15 μm and the lower side thereof is set as 2 to 5 μm, a side wall of the top end of each protrusion will not be too thin to be fragile, and the alignment liquid can be ensured to flow into the recess smoothly.

Furthermore, a depth of the recess 301 in a direction perpendicular to the substrate is 5 to 10 μm.

It is possible to ensure the recess 301 to be filled with a certain amount of the alignment liquid so that a complete alignment film can be formed in a via hole region which is covered by a protrusion when the upper side of the trapezoidal recess is 5 to 15 μm and the lower side thereof is 2 to 5 μm and the depth thereof in the direction perpendicular to the substrate is 5 to 10 μm.

Furthermore, the protrusions 102 are made of resin material.

With the transfer printing plate according to embodiments of the invention, the transfer printing plate comprising a substrate and a plurality of protrusions disposed on and protruding from the substrate and spaced apart from each other, wherein a top end of at least one protrusion is provided with a recess filled with a certain amount of an alignment liquid. When a via hole in a display substrate to be aligned is covered or blocked by a protrusion during forming an alignment film, the alignment liquid in the recess forms the alignment film by printing the alignment liquid in the via hole, such that a complete alignment film can be formed. Therefore, the problem that a via hole region can not be formed with the alignment film due to blocking of the via hole can be avoided. Thus, a uniform alignment film can be obtained and a display quality of a display panel can be improved.

Based on the same inventive concept, an embodiment of the disclosure further provides a method for manufacturing a transfer printing plate comprising:

forming a plurality of protrusions 102 protruding from a substrate 101; and

forming a recess 301 at a top end of at least one protrusion 102,

the recess is configured to receive an alignment liquid, and the alignment liquid in the recess 301 forms an alignment film in a via hole when the via hole of a display substrate to be aligned is covered by the protrusion 102.

Further, the protrusions 102 may be made of resin material.

The method for forming the transfer printing plate particularly comprises:

coating the resin material on the substrate 101 to form a resin layer, with a thickness of the resin layer being generally 15 to 25 μm, and the particular thickness thereof can be set as required;

applying a positive photoresist on the resin layer;

forming the protrusions 102 including the recesses 301 through a patterning process such as exposure or etching by a mask plate including a complete shielding region, a light transmitting region and a half-shielding region, wherein the half-shielding region corresponds to the recess 301, and the complete shielding region corresponds to a remaining part of the protrusion 102 expect the recess 301.

According to other embodiments, a negative photoresist may be used. In this regard, the half-shielding region corresponds to the recess 301, and the light transmitting region corresponds to other part of the protrusion 102 expect the recess 301.

According to other embodiments, it is also possible to form the plurality of protrusions protruding and spaced apart from each other on the substrate and form the recess 301 on the top end of the at least protrusion by machining processes.

typically, each of the recess 301 has a trapezoidal shape in cross-section. In particular, during manufacturing the transfer printing plate, it is possible to form the recess 301 having a rectangular or triangular shape in cross-section.

The recess is easily formed through a patterning process when it has a rectangular, trapezoidal or triangular shape in cross-section. In addition, the recess may also have other shapes such as a semicircular or polygonal shape in cross-section.

Moreover, when the recess has the trapezoidal shape in cross-section, an upper side thereof is 5 to 15 μm, and a lower side thereof is 2 to 5 μm.

In a case where the upper side is 5 to 15 μm and the lower side is 2 to 5 μm, the recess has a reversed trapezoidal shape, which can be easily formed by an existing photolithographic process. Further, in the prior art, a diameter of the top end of each protrusion is typically 10 to 40 μm. when the upper side of the trapezoidal recess is set as 5 to 15 μm and the lower side thereof is set as 2 to 5 μm, a side wall of the top end of each protrusion will not be too thin to be fragile, and the alignment liquid can be ensured to flow into the recess smoothly.

Furthermore, a depth of the recess 301 in a direction perpendicular to the substrate is 5 to 10 μm.

It is possible to ensure the recess 301 to be filled with a certain amount of the alignment liquid so that a complete alignment film can be formed in a via hole region where the via hole is covered by the protrusion when the upper side of the trapezoidal recess is 5 to 15 μm and the lower side thereof is 2 to 5 μm and the depth thereof in the direction perpendicular to the substrate is 5 to 10 μm.

In the protrusions formed by the method according to the embodiment of the disclosure, the top end of the at least one protrusion is provided with a recess filled with the certain amount of the alignment liquid. When a via hole in the display substrate to be aligned is covered by a protrusion during forming the alignment film, the alignment liquid in the recess forms the alignment film by printing the alignment liquid in the via hole, so that a complete alignment film can be formed, which solve the problem that a via hole region can not be formed with the alignment film due to blocking of the via hole. Therefore, a uniform alignment film can be obtained and a display quality of a display panel can be improved.

Obviously, those skilled in the art may make various changes or modifications to these embodiments without departing from the principle and spirit of the disclosure. Thus the disclosure is intended to cover these changes and modifications if these changes and modifications fall within the scope of the claims and their equivalents.

What is claimed is:

1. A transfer printing plate for forming an alignment film, comprising
a substrate; and
a grid point structure comprising a plurality of protrusions disposed on the substrate and spaced apart from each other,
wherein at least one of the plurality of protrusions is provided with a recess at a top end thereof for receiving an alignment liquid, and
wherein the alignment liquid in the recess forms the alignment film in a via hole in a display substrate to be aligned when the via hole is blocked by the protrusion.

2. The transfer printing plate according to claim 1, wherein the recess has a rectangular, trapezoidal or triangular shape in cross-section.

3. The transfer printing plate according to claim 2, wherein when the recess has the trapezoidal shape in cross-section, an upper side of the trapezoidal shape has a size of 5 to 15 μm, and a lower side thereof has a size of 2 to 5 μm.

4. The transfer printing plate according to claim 3, wherein a depth of the recess in a direction perpendicular to the substrate is 5 to 10 μm.

5. The transfer printing plate according to claim 1, wherein the protrusions are made of resin material.

6. A method for manufacturing a transfer printing plate comprising
providing a substrate; and
forming a plurality of protrusions which are spaced apart from each other on the substrate, wherein a recess is formed at a top end of at least one of the protrusions,
wherein the recess is configured to receive an alignment liquid, and when a via hole in a display substrate to be aligned is blocked by the protrusion, the alignment liquid in the recess forms the alignment film in the via hole.

7. The method according to claim 6, wherein the recess has a rectangular, trapezoidal or triangular shape in cross-section.

8. The method according to claim 7, wherein when the recess has the trapezoidal shape in cross-section, an upper side of the trapezoidal shape has a size of 5 to 15 μm, and a lower side thereof has a size of 2 to 5 μm.

9. The method according to claim 8, wherein a depth of the recess in a direction perpendicular to the substrate is 5 to 10 μm.

10. The method according to claim 6, wherein the protrusions are made of resin material.

11. The method according to claim 10, further comprising:
coating resin material on the substrate to form a resin layer;
applying photoresist on the resin layer; and
forming the protrusions including the recesses through a patterning process by using a mask plate including a complete shielding region, a light transmitting region and a half-shielding region,
wherein the half-shielding region corresponds to the recess, and the complete shielding region or the light transmitting region corresponds to a remaining part of the protrusion expect the recess.
